(19) United States
(12) Patent Application Publication
(10) Pub. No.: US 2015/0207002 A1
(43) Pub. Date: Jul. 23, 2015

(54) MONOLITHIC SOLAR CELL ARRAYS AND FABRICATION METHODS

(71) Applicant: Solexel, Inc., Milpitas, CA (US)

(72) Inventors: Mehrdad M. Moslehi, Los Altos, CA (US); Thom Stalcup, Milpitas, CA (US); Michael Wingert, Milpitas, CA (US); Jay Ashjaee, Cupertino, CA (US); Pawan Kapur, Burlingame, CA (US); Homi Fatemi, Milpitas, CA (US)

(21) Appl. No.: 14/475,566

(22) Filed: Sep. 2, 2014

Related U.S. Application Data
(60) Provisional application No. 61/872,035, filed on Aug. 30, 2013.

(51) Int. Cl. H01L 31/0465; H01L 31/02; H01L 31/0236; H01L 31/0224

(52) U.S. Cl. CPC H01L 31/0465; H01L 31/02245; H01L 31/02008; H01L 31/02366

(57) ABSTRACT

Solar cell array solutions including monolithic solar cell arrays and fabrication methods. A first patterned cell metallization contacts base and emitter regions of each of a plurality of solar cells having a light receiving frontside and a backside. An electrically insulating continuous backplane layer is attached to the backside of the solar cells and covers the first cell metallization of each of the solar cells. Via holes through the continuous backplane layer provide access to the first cell metallization. A second cell metallization is connected to the first cell metallization of each of the solar cells and electrically interconnects the solar cells in the array.

### CROSS-REFERENCE TO RELATED APPLICATIONS

This application claims the benefit of U.S. provisional patent application 61/872,035 filed on Aug. 30, 2013, which is hereby incorporated by reference in its entirety.

### FIELD OF THE INVENTION

The present disclosure relates in general to the fields of photovoltaic (PV) solar cells, and more particularly solar cell arrays and modules.

### BACKGROUND

As photovoltaic solar cell technology is adopted as an energy generation solution on an increasingly widespread scale, fabrication and efficiency improvements relating to solar cell and module efficiency, metallization, mechanical support, and fabrication are required. Manufacturing cost and conversion efficiency factors are driving solar cell absorbers ever thinner in thickness and larger in area, thus, increasing the mechanical fragility and complicating processing and handling of these thin absorber based solar cells—fragility effects increased particularly with respect to crystalline silicon absorbers. Solar cells in current photovoltaic modules and array packages may be susceptible to cracks and breakage during module processing (e.g., module encaspulant lamination or tabbing/stringing for cell to cell interconnection) and subsequently during field installation and operation, resulting in power loss and reliability degradation.

At the solar cell array or module level, cell to cell interconnection often involves tabbing and/or stringing already-fabricated cells for module-level electrical interconnections (e.g., using a flux interconnect ribbon) which typically requires on-cell soldering and solder joints. In some instances, the soldering process and solder joints may result in some performance degradation due to thermal/mechanical stresses and may also result in field reliability failures due to solder joint and cell-to-cell ribbon interconnection failures. Further, the costs of tabbing and stringing materials (e.g., Cu ribbon, solder), processes, and equipment may add to overall capital expenditures and manufacturing costs.

Typically, in conventional prior art crystalline silicon modules cell-level metallization and module-level electrical interconnections (for cell-to-cell interconnection processes such as tabbing and bussing) use separate production processes and may even use different materials (e.g., silver and aluminum for solar cells vs solder coated copper ribbons for cell to cell interconnections). For instance, traditional front-contact solar cells often use fired silver and aluminum pastes for cell-level metallization and the modules use copper ribbons and soldering for module-level interconnections—thus there is no commonality and/or sharing of electrical interconnection processes or materials between the cell metallization and module interconnection (tabbing, bussing) processes. In traditional solar modules, the solar cells are already fully fabricated, tested and sorted prior to solar module fabrication.

Often, in conventional or prior art solar modules due to the soldered tabs/ribbons interconnecting adjacent solar cells minimum spacing between the adjacent solar cells (typically at least 1 mm to 2 mm) is required in order to meet the reliability requirements for modules in the field by minimizing or eliminating the interconnection failures in the field. This spacing between the solar cells reduces the overall total-area module efficiency (due to the larger cell-to-module efficiency drop).

Conventional (prior art) solar modules are often manufactured, for example, as follows: (i) test and sort fabricated solar cells at the end of the cell fabrication process flow; (ii) tab/string the sorted solar cells to make series-connected strings of cells; (iii) module lay-up including module encapsulants, bussing, and preparation with cleaned glass cover, EVA encapsulant sheets and back sheet (e.g., vinyl based film); (iv) module lamination; (v) module encapsulant trimming, (vii) framing and junction box/electrical connection; (viii) final module test. Further, for example, the fabricated cells must be pre-sorted and tested (for cell binning) prior to module tabbing/stringing as a defective cell may substantially alter the power generation of the module—in other words solar cells (e.g., crystalline silicon solar cells) are processed through cell fabrication process lines and then tested and sorted in preparation for the subsequent solar module assembly. Often, there is an increased risk of cell breakage during and after module fabrication, resulting in reduced manufacturing yield and increased PV module manufacturing cost.

### BRIEF SUMMARY OF THE INVENTION

Therefore, a need has arisen for photovoltaic solar cell array solutions that decrease fabrication complexity and provide increased solar cell array performance. In accordance with the disclosed subject matter, photovoltaic solar cell arrays and fabrication methods are provided which substantially eliminates or reduces disadvantages and deficiencies associated with previously photovoltaic solar cell arrays and fabrication methods.

According to one aspect of the disclosed subject matter a photovoltaic solar cell array is provided. A first patterned cell metallization contacts base and emitter regions of each of a plurality of solar cells having a light receiving frontside and a backside. An electrically insulating continuous backplane layer is attached to the backside of each of the solar cells and covers the first cell metallization of each of the solar cells. Via holes through the continuous backplane layer provide access to the first cell metallization. A second cell metallization is connected to the first cell metallization of each of the solar cells and electrically interconnects the plurality of solar cells in the array.

These and other aspects of the disclosed subject matter, as well as additional novel features, will be apparent from the description provided herein. The intent of this summary is not to be a comprehensive description of the claimed subject matter, but rather to provide a short overview of some of the subject matter's functionality. Other systems, methods, features and advantages here provided will become apparent to one with skill in the art upon examination of the following FIGUREs and detailed description. It is intended that all such additional systems, methods, features and advantages that are included within this description, be within the scope of any claims.

### BRIEF DESCRIPTION OF THE DRAWINGS

The features, natures, and advantages of the disclosed subject matter may become more apparent from the detailed description set forth below when taken in conjunction with the drawings in which like reference numerals indicate like features and wherein:

FIG. 1 is a cross-sectional diagram of a representative interdigitated back contact (IBC) back junction solar cell in a solar cell array/module;

FIG. 2 is a cross-sectional diagram of an array/module of the back contact back junction solar cells;

FIG. 3A is a diagram showing a top view of a representative five by six solar cell array/module;

FIG. 3B is a schematic top view of the cell interconnection and current flow of a representative 4 by 6 solar cell array;

FIG. 4 is a process flow for forming continuous backplane attached monolithic solar cell arrays/modules;

FIGS. 5 and 6 are drawings of the backside of an interdigitated back contact solar cell showing a first level metal and a second level metal, respectively;

FIGS. 7A and 7B are top views of cell interconnection and current flow of a representative 2 by 2 solar cell array;

FIGS. 8 and 9 are selected cross-sectional diagrams of portions of a back-contact solar cell along cross-sectional axis showing orthogonal M1/M2 emitter connection and orthogonal M1/M2 base connection, respectively; and

FIGS. 10 and 11 are process flows for forming a monolithic solar cell array/module.

### DETAILED DESCRIPTION

The following description is not to be taken in a limiting sense, but is made for the purpose of describing the general principles of the present disclosure. The scope of the present disclosure should be determined with reference to the claims. Exemplary embodiments of the present disclosure are illustrated in the drawings, like numbers being used to refer to like and corresponding parts of the various drawings. The dimensions of drawings provided are not shown to scale.

And although the present disclosure is described with reference to specific embodiments and components, such as a back contact back junction solar cell, one skilled in the art could apply the principles discussed herein to other solar cell structures (such as front contact or emitter wrap through—EWT—solar cells), fabrication processes (such as various metallization methods and materials, for example plating), as well as continuous backplane materials and formation, for example a dielectric material deposition), technical areas, and/or embodiments without undue experimentation.

Importantly, the drawings provided herein depicting aspects of metallization patterns and solar cell cross-sections are not drawn to scale. Additionally, the metallization diagrams shown presented for descriptive purposes and may have different x and y axis scales. The following are provided as exemplary dimensional embodiments, however individual solar cells, metallization materials, and various requirements may dictate continuous backplane and metallization pattern dimensions.

The present application provides effective and efficient solar cell array and module solutions having substantially improved fabrication method and photovoltaic structure advantages. The novel solar cell and metallization structures described herein utilize a multi-layer metallization structure, such as a two-level metallization structure, comprising an on-cell base and emitter metallization first level metal (M1) and a second level metal (M2) collecting power (voltage and current) from the first level metal (hence, completing the solar cell metallization) and also forming the overall cell to cell interconnections. The second level metal (M2) may comprise an interdigitated pattern of base and emitter current collection fingers and optionally solar cell base and emitter busbars. The first level metal (M1) may comprise an interdigitated back contact metallization structure with a relatively fine pitch (much finer pitch than the second level metal pitch), being orthogonal/perpendicular or in some instances parallel to the interdigitated fingers of M2 and optionally base and emitter M2 busbars. A relatively thin continuous electrically insulating backplane formed between M1 and M2 and attached to the solar cells provides solar cell structural support, M1 electrical insulation, and allows for solar cell fabrication (particularly M2 fabrication and solar cell frontside processing) processing improvement. The solar cell array embodiments provided herein utilize a continuous backplane sheet, preferably a flexible material closely CTE-matched with the solar cell semiconductor substrate material (e.g., crystalline silicon for silicon solar cells), laminated or otherwise attached to, for example, a plurality of back-contact/back-junction solar cells prior to completion of the remaining solar cell (and monolithic module) manufacturing process steps. For example, the laminated backplane embodiments provided herein allow for variable readily adaptable M2 metallization patterning and provide solar cell backside and M1 protection during subsequent processing—key advantages in plasma deposition processing, thermal processing, and/or wet chemistry processing steps for the remaining solar cell production steps.

In a multi-level metallization design, for example a two-level metal design comprising a first level on-cell metal M1 (for instance, a fine-pitched interdigitated metallization structure comprising aluminum or another suitable metal), and a second level metal M2 (for instance, a coarse-pitched interdigitated metallization structure comprising aluminum or copper or another suitable metal), M1 may comprise interdigitated base and emitter lines (for instance, with base-emitter finger pitch of <2 mm and preferably <1 mm) and M2 (preferably with its fingers substantially orthogonal/perpendicular to M1 fingers and with a much coarser base-emitter pitch compared to M1) serves as the electrical connector among M1 base and emitter lines (i.e., a busbarless M1 pattern while the optional cell busbars may be placed on the M2 pattern). The metal layers in the disclosed multi-level metal designs are separated by a dielectric or an electrically insulating layer, such as a resin/fiber based prepreg material or alternatively a suitable plastic or polymer based material, forming a continuous backplane for each of the plurality of solar cells in the solar cell array placed on the continuous backplane. Importantly, the continuous backplane should preferably be relatively closely CTE (Coefficient of Thermal Expansion) matched to the CTE of the semiconductor absorber (e.g., crystalline silicon) so as to minimize CTE mismatch stress or warpage effects during thermal processing—for example a specially formulated aramid fiber resin prepreg material provides close CTE matching with silicon while providing flexibility, electrical insulating, thermal and chemical stability, and other desirable processing and reliability characteristics such as effective crack-free lamination. M1/M2 interconnection structures include conductive material filled vias through the insulating layer (e.g., an insulating dielectric layer such as prepreg backplane) positioned between M1 and M2—laminated or attached to the backsides of the solar cells after formation of the patterned M2 layer.

The continuous backplane material attached to the backsides of a plurality of solar cells and placed between patterned M1 and M2 layers may be a thin (e.g., between approximately 25 microns and 1 mm and preferably between approximately 25 microns and 250 microns) sheet of a polymeric material with sufficiently low coefficient of thermal expansion (CTE) which is closely matched to that of the semiconductor absorber layer in order to avoid causing excessive thermally induced stresses and warpage on the solar cell array. Moreover, the backplane material should meet process integration requirements for the backend cell fabrication processes, in particular chemical resistance during wet texturing of the cell frontside and thermal stability during the PECVD deposition of the frontside passivation and anti-reflection coating (ARC) layer. Moreover, the electrically insulating backplane material should also meet the module-level lamination process and long-term reliability requirements. While various suitable polymeric (such as plastics, fluropolymers, prepregs, etc.) and suitable non-polymeric materials (such as glass, ceramics, etc.) may be used as the backplane material, backplane material choice depends on many considerations including, but not limited to, material cost, ease of process integration, reliability, pliability, mass density, etc.

A preferable material choice for the backplane material is prepreg and more particularly an aramid fiber resin based prepreg. In some instances, a non-woven aramid fiber is particularly advantageous. Prepreg sheets are used as building blocks of printed circuit boards and may be made from combinations of resins and CTE-reducing fibers or particles. The backplane material may be an inexpensive, low-CTE (typically with CTE <10 ppm/° C., or preferably with CTE <5 ppm/° C.), thin (for example 25 to 250 microns, and more particularly in the range of about 50 to 150 microns) prepreg sheet which is relatively chemically resistant to texturization chemicals and is thermally stable at temperatures up to at least 180° C. (or preferably at least about 300° C., in non-oxidizing ambient). Generally, prepregs are reinforcing materials pre-impregnated with resin and ready to use to produce composite parts (prepregs may be used to produce composites faster and easier than wet lay-up systems). Prepregs may be manufactured by combining reinforcement fibers or fabrics with specially formulated pre-catalyzed resins using equipment designed to ensure consistency. Covered by a flexible backing paper, prepregs may be easily handled and remain pliable for a certain time period (out-life) at room temperature. Further, prepreg advances have produced materials which do not require refrigeration for storage, prepregs with longer shelf life, and products that cure at lower temperatures. Prepreg laminates may be cured by heating under pressure. Conventional prepregs are formulated for autoclave curing while low-temperature prepregs may be fully cured by using vacuum bag pressure alone at much lower temperatures.

The continuous prepreg sheet may be attached to the solar cells backsides using a vacuum laminator. Upon applying a combination of heat and pressure, the thin prepreg sheet is permanently laminated or attached to the backsides of the plurality of partially-processed (or even fully-processed) solar cells. In the case of partially-processed solar cells, subsequent post-lamination fabrication process steps may include: (i) completion of the texture and passivation processes on the sunnysides (frontsides) of the solar cells, (ii) completion of the high conductivity metallization (M2) on the backsides of the solar cells (which may comprise part of the solar cell backplane). The high-conductivity metallization M2 layer (for example comprising aluminum, copper, or silver, with aluminum and/or copper being preferred compared to silver because of much lower material cost) comprising both the emitter and base polarities is formed on the laminated backplane attached to the backsides of the solar cells.

The solar cells described utilize a two-level metallization scheme comprising a preferably busbarless (although optional busbars may be used) first-level contact metallization (M1) using a relatively thin patterned metal (e.g., thin aluminum formed by screen printing of an aluminum paste or inkjet printing of an aluminum ink, or alternatively plasma sputtering from an aluminum target followed by laser ablation or wet etch patterning) formed directly on the backside of each solar cell prior to continuous backplane lamination, and a second level thin patterned metal M2 (e.g., comprising approximately 3 to 5 microns thick Al) or alternatively, about 1 to several microns of copper, either case preferably capped with a solderable coating such as tin) formed after continuous backplane lamination to a plurality of solar cells. The patterned M2 layer may also be formed by using plating or lamination and patterning of a high-conductivity metal foil (comprising copper or aluminum). The M1 and M2 layers are separated by the continuous backplane and interconnected at designated regions through conductive via plugs (with the conductive via plugs formed during M2 formation). M1 has fine-pitch pattern and M2 preferably is orthogonal (or substantially perpendicular) to M1 and has coarse pitch pattern (hence, fewer base and emitter fingers compared to M1). Patterned M2 completes both the cell-level and cell array or module-level monolithic electrical interconnections for all the solar cells laminated to the continuous backplane—thus in some instances eliminating the need for separate tabbing/bussing/soldering. Further, M2 may form array/module level bussing or interconnections when desired for array/module electrical interconnection design. The continuous backplane-attached monolithic module (or array of solar cells, for example in some instances a number of solar cell arrays formed in accordance with the disclosed subject matter may be stitched together to make up a larger and higher power solar module—in other words a final end use module may comprise an array, a plurality of arrays, or a fraction of an array of solar cells) may then be laminated either as a frameless flexible and/or lightweight PV module (no cover glass) or as a rigid glass covered PV module.

In some instances, voltage and current scaling (for example, higher voltage and lower current solar cells) may relax and reduce M2 conductivity requirements and constraints. For example, in consideration with other factors, utilizing a thinner M2 metal (e.g., about 2 to 5 microns thick evaporated aluminum by PVD or about 1 to few microns of copper formed by plasma sputtering or evaporation) as compared to thicker M2 metallization (e.g., about 50 to 80 microns thick electroplated copper). Importantly, the thickness of M1 and M2 metallization layers may also be adjusted based on the number, dimensions, and shape of the interdigitated fingers on the M1 layer and M2 layer. In most applications, it will be preferable that M1 is patterned with finer interdigitated fingers as compared to the interdigitated fingers of M2. However, the cell structures and fabrication embodiments provided are applicable to various dual level metallization schemes utilizing a continuous backplane and M2 metallization layer.

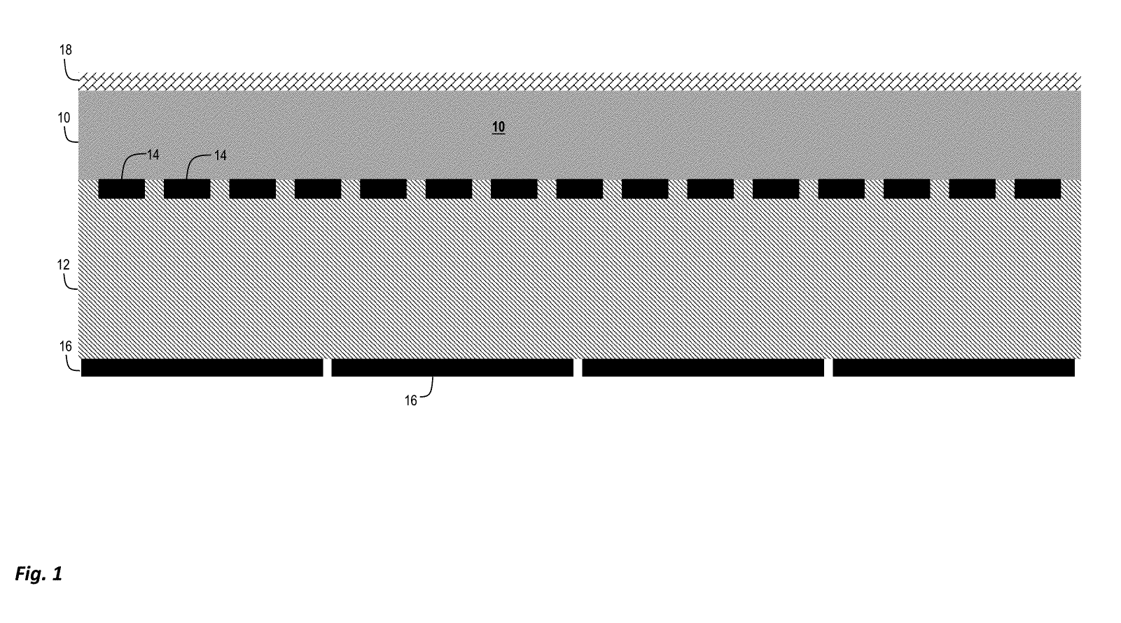

FIG. 1 is a cross-sectional diagram of a representative interdigitated back contact (IBC) back junction solar cell in a solar cell array/module in accordance with the disclosed subject matter. On-cell metallization (also referred to as M1 or first level metal) 14 contacts base and emitter regions (not shown) on the backside of semiconductor absorber 10 (e.g., a standard sized solar cell, for example 156 mm by 156 mm, 210 mm by 210 mm, square or pseudo square solar cell—or a solar cell of any desired shape and size). Continuous backplane 12 is attached to on-cell metallization 14 and the backside of semiconductor 10. Second level metal 16 (also referred to as M2) is positioned on continuous backplane 12 and electrically connected to M1 (M1 to M2 electrical connections or conductive via plugs not shown). For example, M2 may be connected to M1 by conductive vias through continuous backplane 12. Second level metal 16 electrically connects to additional back contact back junction solar cells thus providing electrical interconnections in an array or module comprising a plurality of solar cells. Passivation and anti-reflection coating (ARC) 18 is positioned on the frontside (sunnyside) of semiconductor absorber 10.

Semiconductor absorber 10 may be a thin crystalline silicon (for example having a thickness in the range of approximately 10 to 100 micrometers) back contact back junction solar cell absorber. On-cell metallization (M1) 14 forming base and emitter metallization for semiconductor 10 may be an interdigitated metallization pattern (e.g., in one instance a busbarless thin aluminum layer of base/emitter interdigitated fingers, formed by printing or PVD) electrically contacting base and emitter regions on the backside of semiconductor absorber 10. On-cell metallization 14 may be a, for example, by a patterned PVD or screen-printed (or inkjet-printed) metal layer such as aluminum or other suitable conductive metal such as nickel. Continuous backplane 12 may be a laminated flexible polymeric sheet such as prepreg having a thickness preferably in the range of approximately 50 to 200 micrometers thick and formed across a plurality of semiconductor absorbers having base and emitter metallization patterns. Second level metal (M2) 16 may be a patterned structure of base/emitter interdigitated fingers also optionally having a base busbar and an emitter busbar for each solar cell. Importantly, although shown as a parallel M1/M2 pattern in FIG. 1, M2 may be formed in an orthogonal pattern with respect to M1—in other words the interdigitated fingers of M1 (on-cell metallization 14) are made substantially perpendicular/orthogonal to the interdigitated fingers of M2 (second level metal 16). Second level metal 16 may be a patterned metal layer of a high electrical conductivity metal such as aluminum and/or copper formed by PVD processing such as evaporation and/or plasma sputtering (or alternatively formed by other methods such as copper plating). Passivation and anti-reflection coating (ARC) layer 18 is formed on the front/sunnyside (and optionally textured surface) of semiconductor absorber 10. For example, passivation and ARC layer 18 may be a PECVD passivation and silicon nitride ARC stack.

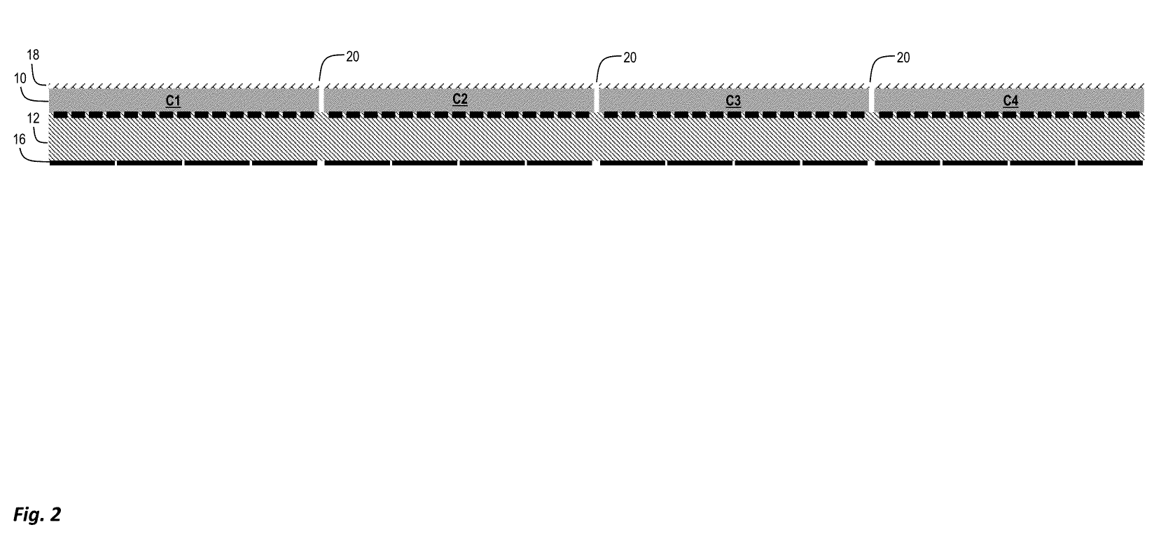

A continuous backplane, such as that shown in FIG. 1, is formed (e.g., laminated or otherwise attached) across a plurality of back contact back junction solar cells forming an array or module of solar cells. FIG. 2 is a cross-sectional diagram of an array/module of the back contact back junction solar cells of FIG. 1 in accordance with the disclosed subject matter. As shown in FIG. 2, continuous backplane 12 is positioned on the backside of each of four solar cells C1, C2, C3, and C4. The absorber of each solar cell C1, C2, C3, and C4 are separated by separation width 20. The actual number of solar cells laminated or attached to each continuous backplane sheet may be N×M wherein N and M are preferably integer numbers with N×M≧2. For instance, N×M=6×5=30 or N×M=6×10=60 (or any other desired format which may be supported by the production toolset).

Prior to backplane lamination, the solar cell base and emitter contact metallization pattern is formed directly on the cell backside, for instance using a thin layer of screen printed or inkjet printed or plasma sputtered (PVD) or evaporated aluminum (or aluminum silicon alloy or Al/NiV/Sn stack) material layer. This first layer of metallization (herein referred to as M1) defines the solar cell contact metallization pattern, for example fine-pitch interdigitated back-contact (IBC) conductor fingers defining the base and emitter regions of the IBC cell. The M1 layer extracts the solar cell current and voltage (hence the solar cell power) and transfers the solar cell electrical power through the conductive via plugs formed in the backplane to the second level/layer of high-conductivity solar cell metallization (herein referred to as M2) formed after M1. The conductive via plugs can be formed concurrently during the formation of the patterned M2 layer after laser drilling of via holes in the backplane layer.

Solar cells may are laminated into a relatively large format structure where a plurality of solar cells (e.g., N rows and M columns resulting in an array of N×M cells) are attached to a continuous sheet of backplane (e.g., a flexible approximately 50 to 250 μm thick prepreg sheet) material, enabling subsequent monolithic M2 metallization (i.e., an M2 metallization layer formed across the plurality of solar cells on a continuous backplane sheet) to complete cell and module metallization. In operation, a very-low-cost backplane layer may be bonded to, for example, a plurality of solar cells for permanent support and reinforcement as well as to support the high-conductivity cell metallization of each of the solar cells. The backplane material may be made of a thin (for instance, a thickness in the range of approximately 50 to 250 microns and in some instances in the range of 50 to 150 microns), flexible, and electrically insulating polymeric material sheet such as an inexpensive prepreg material commonly used in printed circuit boards which meets cell process integration and reliability requirements. The continuous backplane covers and protects the solar cell backside and first level metallization M1 for frontside/sunnyside processing including, for instance, frontside texturization, and passivation and anti-reflection coating (ARC) deposition process.

After formation of the backplane (on or in and around M1 layer), a higher conductivity M2 layer is formed on the backplane. Via holes (in some instances up to hundreds or thousands of via holes per solar cell) are drilled into the backplane (for example by laser drilling) and may have diameters in the range of approximately 50 up to 500 microns (particularly in the diameter range of about 100 to 300 microns). These via holes land on pre-specified landing pad regions of M1 for electrical connection between the patterned M2 and M1 layers through conductive plugs formed in these via holes. Subsequently or in conjunction with the via holes filling and conductive plug formation, the patterned high-conductivity metallization layer M2 is formed (for example by plasma sputtering, plating, evaporation, or a combination thereof—using an M2 material comprising, for instance, aluminum, Al/NIV, Al/NiV/Sn, or copper or solder-coated copper). For an interdigitated back-contact (IBC) solar cell with fine-pitch IBC fingers on M1 (for instance, hundreds of fingers), the patterned M2 layer may be designed orthogonal to M1—in other words rectangular or tapered M2 fingers substantially perpendicular to the M1 fingers. Because of this orthogonal transformation, the patterned interdigitated M2 layer may have far fewer and wider IBC fingers than the M1 layer (for instance, by a factor of about 10 to 50 fewer M2 fingers with respect to the M1 fingers). Hence, the M2 layer may be formed in a much coarser pattern with wider IBC fingers than the M1 layer. Optional solar cell busbars may be positioned on the M2 layer, and not on the M1 layer (in other words a busbarless M1), to eliminate electrical shading losses associated with on-cell busbars. As both the base and emitter interconnections and busbars may be positioned on the M2 layer on the solar cell backside backplane, electrical access is provided to both the base and emitter terminals of the solar cell on the backplane from the backside of the solar cell.

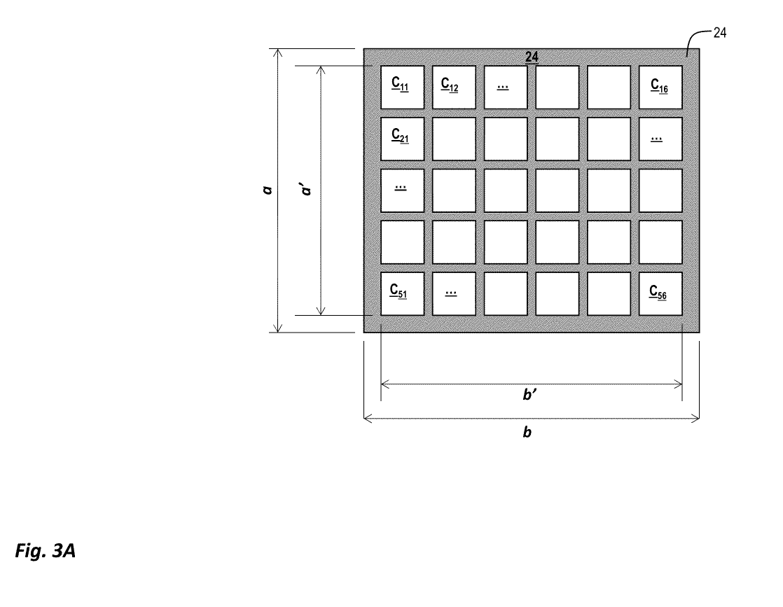

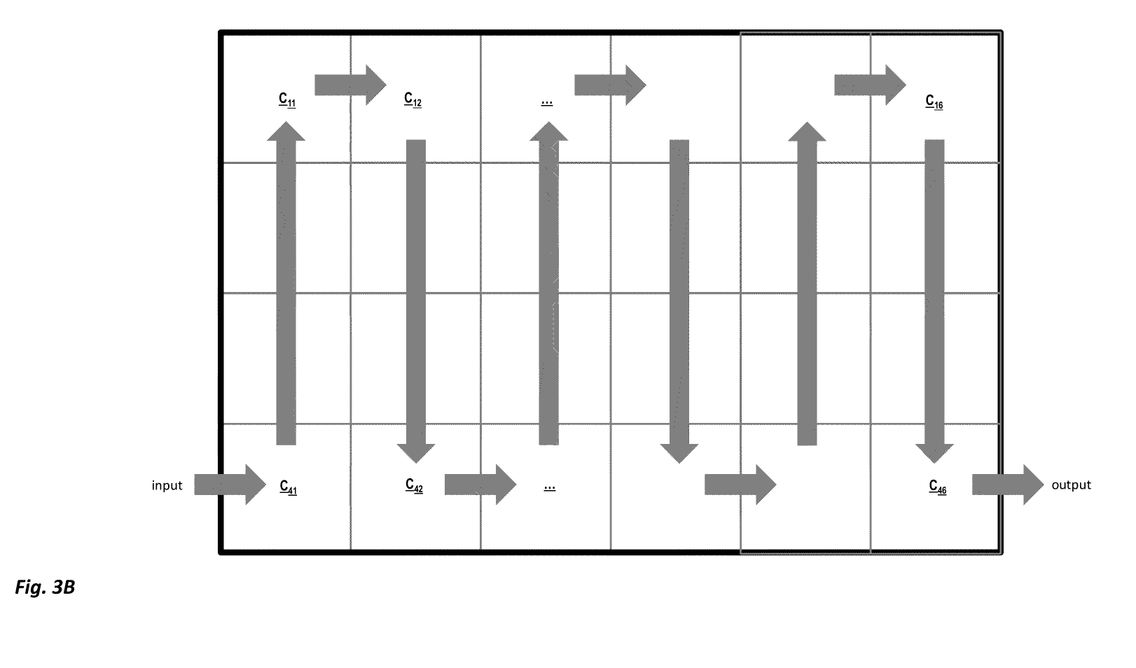

FIG. 3A is a diagram showing a top view of a representative five by six (N×M=5×6=30) solar cell array/module in accordance with the disclosed subject matter. Continuous backplane 24 (e.g., a continuous laminated prepreg sheet) is attached to the backside of back contact solar cells C₁₁ through C₅₆. Continuous backplane 24 provides, among other advantages, mechanical support to solar cells C₁₁ through C₅₆, electrical insulation between M1 and M2 backside metallization layers, and fabrication advantages such as a protection of the solar cell backsides and on-cell metallization M1 during backend frontside processing (e.g., texture and passivation processes) as well as providing a handling component. For example, the following dimensions are provided as exemplary: the panel backplane thickness may be in the order of approximately 0.2 mm; in the case of 156 mm by 156 mm solar cells with 1 mm spacing between cells the module provides an active solar array/module area of 784 mm (dimension a′ in FIG. 3A) by 941 mm (dimension b′ in FIG. 3A) and continuous backplane 24 with dimensions of 814 mm (width dimension a in FIG. 3A) and 941 mm (height/length dimension b in FIG. 3A). A continuous backplane handle perimeter surrounds the solar cell array/module and may act as a processing handle during fabrication to protect the solar cells as well as provide a structure (e.g., landing pad) for the placement of solar cell embedded power electronics which may then be laminated within module encapsulant. Importantly, if module bussing is desired, for example in the case of a hybrid parallel series connected solar cell array/module, the module bussing may be positioned on the continuous backplane handle and monolithically formed as M2 metallization—in other words, M2 may be formed outside the active cell area for applications such as module bussing or power electronics parts placement.

FIG. 3B is a schematic top view of the cell interconnection and current flow of a representative 4 by 6 solar cell array/module produced on a continuous backplane, comprising solar cells C₄₁ through C₄₆. Second level metal M2 provides cell to cell interconnections, for example emitter to base and base to emitter interconnections for series connections of the solar cells. The solar cells of the solar cell array of FIG. 3B are connected in series in an all-series interconnection pattern. Alternatively, these cells or groups of cells within the array may be connected in parallel or a combination of parallel and series. Further, the number and position of inputs and outputs may be adjusted dependent on, for example, cell metallization current requirements. Importantly, the monolithic solar cells arrays (i.e., solar cells formed on a continuous backplane sharing the same backplane and M2) provided herein may form a module themselves or subsequently be integrated into an encapsulated module structure (for example two 6 by 5 arrays combined/stitched together to form a 6 by 10 array or a 5 by 12 array). Thus, the metallization pattern may be designed to enable subsequent stitching of at least two monolithic array/modules prior to the final module lamination in order to manufacture larger solar PV modules with more output power. Conversely, the metallization pattern may be designed to enable subsequent cutting of the monolithic cell array/module prior to the final module lamination into at least two smaller monolithic cell arrays/modules to manufacture smaller solar PV modules.

In other words, M2 metallization pattern can be effectively programmed, for instance, by laser ablation pattern design, to interconnect the solar cells in the monolithic array/module in a desired electrical interconnection configuration such as all-series or hybrid parallel-series to achieve the desired combination of current and voltage for the monolithic array/module. This programming includes variable M2 design corresponding to each cell within the array—in others words solar cell 1 and solar cell 2 in the array/module may have different M2 metallization designs including, for example, inverted metallization patterning, differently shaped interdigitated fingers, and/or varying busbar shapes and placement. The M2 metallization pattern may form cell to cell interconnection patterns such as all-series or hybrid parallel-series configurations using laser metal ablation patterning and depending on the end-market and application requirements (e.g., module current and voltage). In some instances, a preferable interconnection arrangement for the cells in the monolithic modules is an all-series interconnection of the solar cells and in other it may be preferred to scale current and voltage using hybrid parallel-series cell interconnection combinations.

Power electronics may be integrated and embedded in the monolithic solar cell arrays and modules provided herein. A combination of the continuous backplane coupled with M2 metallization design flexibility allows for power electronic integration. For example, embedded electronics components may be mounted onto the continuous backplane and soldered (or attached by conductive adhesive) to the patterned M2 regions after completion of the patterned M2 metallization structure on the continuous backplane and prior to the final module assembly lamination. Embedded electronics components may include one or a combination of: (i) shade management bypass switches (e.g., Schottky barrier rectifiers) on the solar cells, (ii) Maximum Power-Point Tracking (MPPT) DC-to-DC or DC-to-AC power optimizer electronics for solar cells, (iii) Remote Access Module Switch (RAMS) electronics for safety and regulatory compliance as well as module power and temperature data acquisition. Additionally, the continuous-backplane-attached monolithic arrays and modules may also be used in conjunction with external Balance-of-System (BOS) components including but not limited to DC-to-AC microinverters or string inverters.

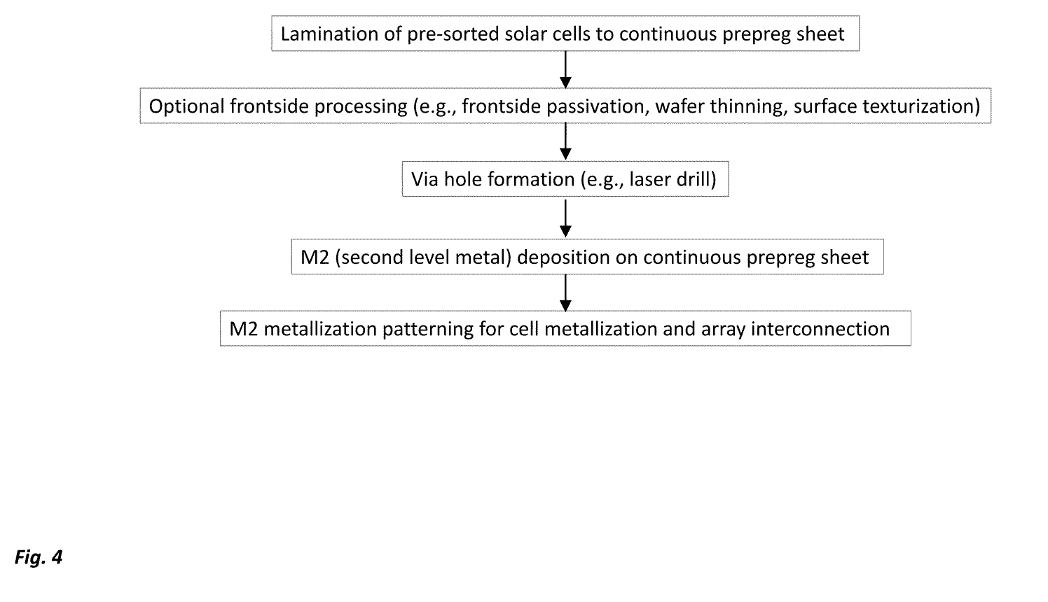

FIG. 4 is a process flow for forming continuous backplane attached monolithic solar cell arrays/modules in accordance the disclosed subject matter starting with pre-sorted interdigitated back contact back junction solar cells with patterned backside M1(on-cell first level) metallization. First a lay-up or arrangement of a plurality of partially processed solar cells on large module-size continuous prepreg sheet is prepared. This may include lamination boards having closely matched coefficients of thermal expansion (CTE) to the prepreg backplane and absorber materials to reduce thermal stress. Next the pre-sorted solar cells are laminated to the continuous prepreg sheet in a heated process using a batch laminator. Optionally, subsequent solar cell frontside processing may be performed as the continuous backplane provides mechanical support and also covers/buries and thus protects the sensitive solar cell absorber backsides and on-cell metallization M1. Subsequent post-lamination frontside processing may include wafer thinning (for example silicon wet etching), surface texture etching, and frontside passivation and ARC formation using PECVD. Via holes are formed in the continuous prepreg backplane, for example using laser drilling, to access the cell M1 metallization (on-cell first level metal). M2 metallization (second level metal) is formed on the back of the prepreg sheet and fills vias to electrically contact M1, for example an aluminum evaporation plus sputtered nickel vanadium (NiV) layer, or a plasma sputtered copper layer capped with plasma sputtered tin. In some instances, the vias may be covered or at least partially filled with conductive metallization and M2 may be deposited in separate steps and in other instances M2 deposition at least partially covers or partially fills the vias in the same M2 deposition or formation step. Then integrated M2 metallization patterning for cell and cell array connection is performed (e.g., laser ablation patterning or masked wet etch patterning).

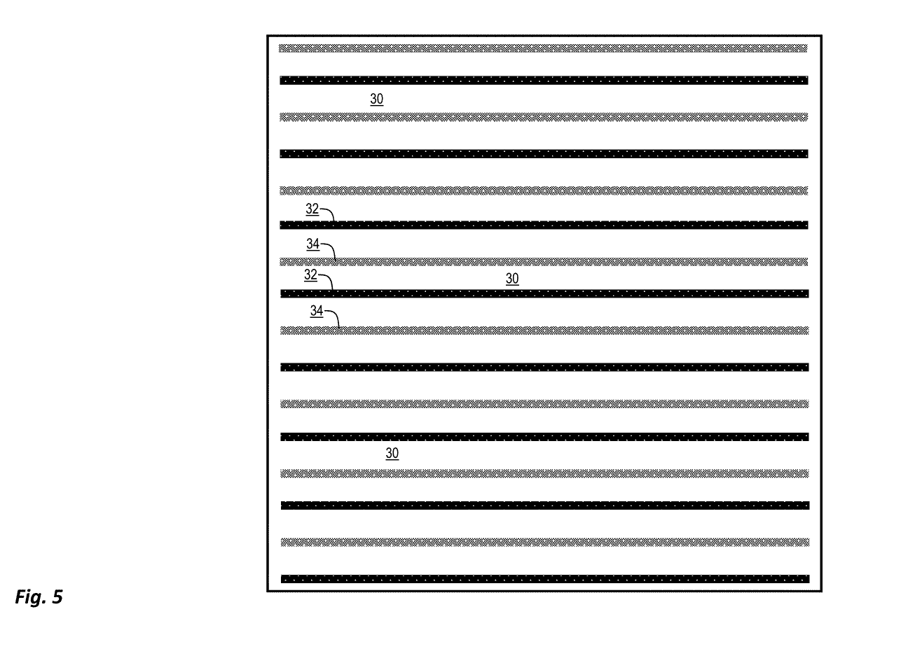

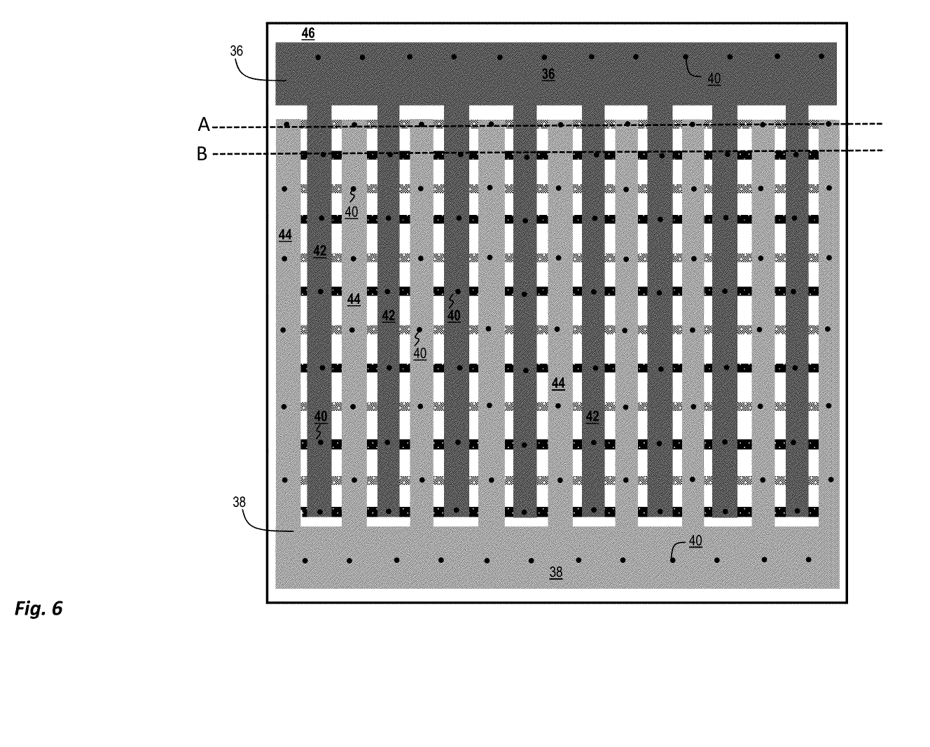

FIGS. 5 and 6 are drawings of the backside of an interdigitated back contact solar cell showing a first level metal and a second level metal, respectively. FIG. 5 is drawing of the backside of a back contact back junction solar cell showing an on-cell first level metal base and emitter metallization pattern (M1) of base fingers 32 and emitter fingers 34 patterned over the bulk of the back contact solar cell for majority and minority carrier collection (metallization patterns not shown to scale). Exposed backside surface 30 includes the portion of the backside surface not covered by the on-cell first level metal M1. The first level metal base and emitter metallization patterns shown herein may correspond to base and emitter regions of the solar cell (not shown).

FIG. 6 is drawing of the backside of an interdigitated back contact back junction solar cell showing second level metallization (M2) on continuous backplane 46 (e.g., a prepreg backplane). The interdigitated M2 pattern comprises an interdigitated pattern of base fingers 42 and emitter fingers 44 patterned over the bulk of the back contact solar cell and connected to the base and emitter metallization of M1, respectively, by electrically conductive via plugs 40 (metallization patterns not shown to scale). Further, base busbar 36 is connected to underlying base fingers 32 and emitter busbar 38 is connected to underlying emitter fingers 34 by conductive via plugs. Here it should be noted although one conductive via 40 is shown for this transfer and each transfer in the drawings provided, multiple via plugs and/or via size may be adjusted in accordance with M1/M2 electrical interconnection requirements.

Importantly, while base fingers 42 and emitter fingers 44 are shown as having a rectangular shape, base fingers 42 and emitter fingers 44 may be designed in a number of geometric or non-geometric designs. Particularly, base fingers 42 and emitter fingers 44 may be tapered with a wider side proximate the fingers corresponding busbar (i.e., base fingers 42 wider proximate base busbar 36 in FIG. 6) to improve current collection efficiency and to reduce the parasitic ohmic losses. It is to be noted, the interdigitated finger and busbars of FIGS. 5 and 6 are not drawn to scale and dimensions and number of fingers may vary (for example M1 may comprise on the order of hundreds of interdigitated fingers and the M2 busbars may have varying width thickness depending on current requirements).

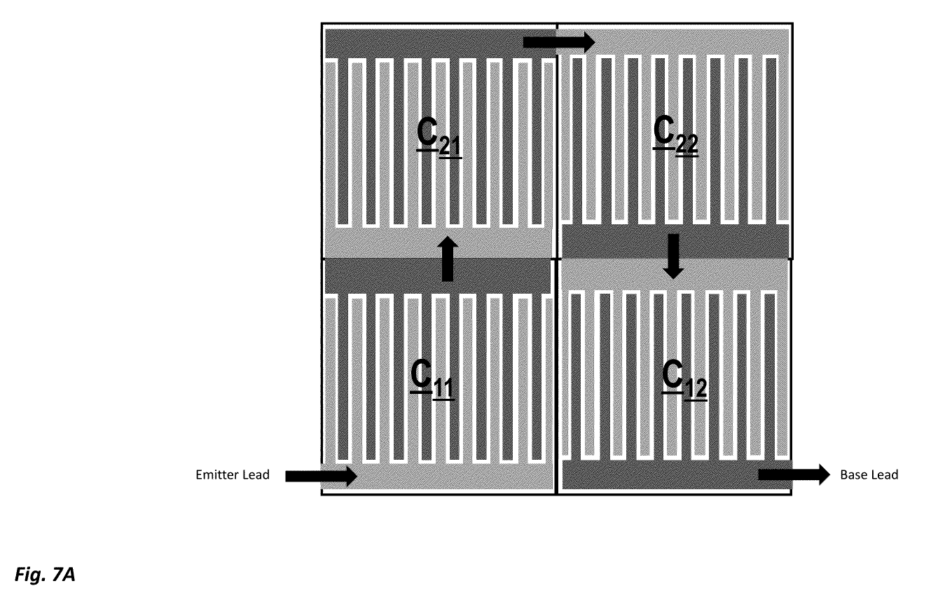

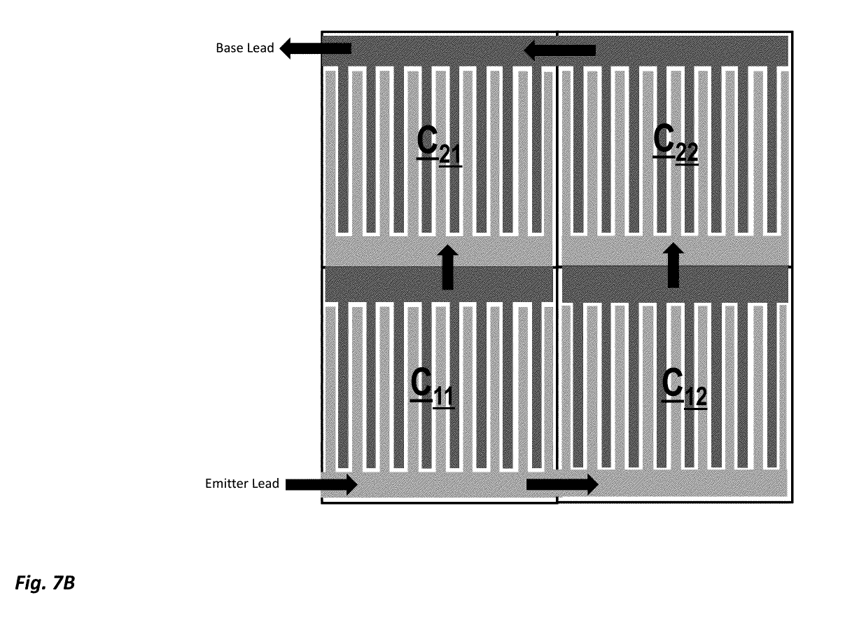

FIGS. 7A and 7B are top views of cell interconnection and current flow of a representative 2 by 2 solar cell array of the solar cells of FIG. 6. As shown in FIG. 7A, second level metal M2 provides cell to cell interconnection from solar cell C₁₁ through C₁₂, for example base to emitter (and vice versa) interconnection. The solar cells of the solar cell array of FIG. 7A are connected in series in an all-series interconnection pattern. Alternatively, these cells or groups of cells within the array may be connected in parallel or a combination of parallel and series (also called a hybrid parallel-series interconnection pattern). As shown in FIG. 7B, second level metal M2 provides cell to cell interconnection from solar cell C₁₁ through C₂₁, for example base to emitter (and vice versa) interconnection. The solar cells of the solar cell array of FIG. 7B are connected in series in a combination/hybrid parallel and series interconnection pattern.

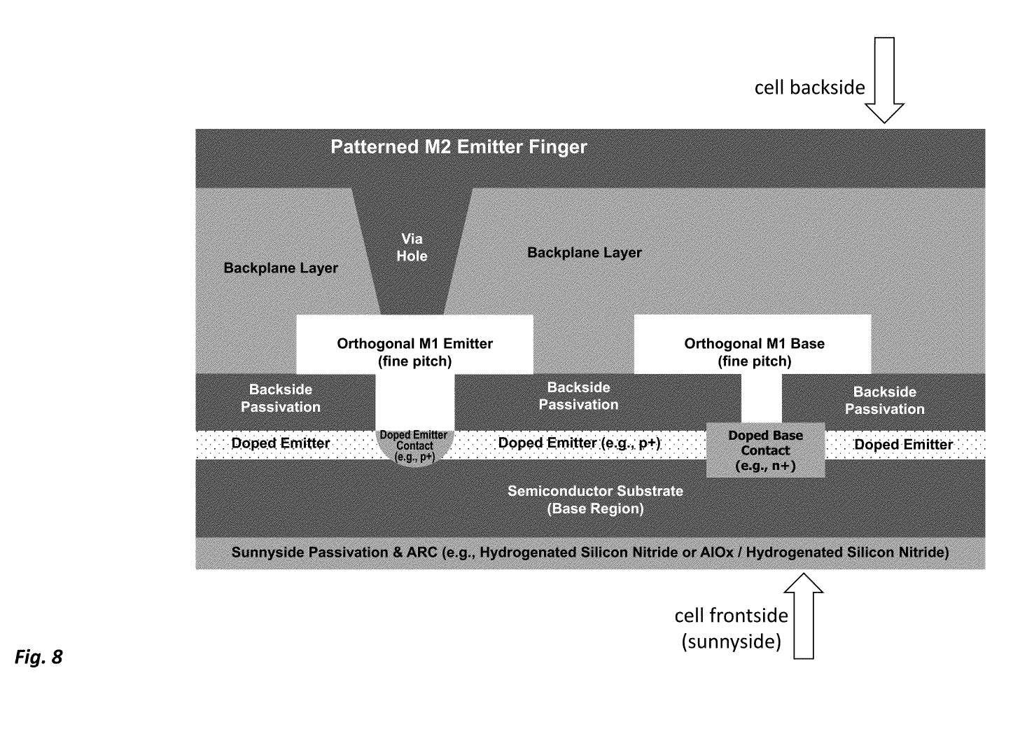

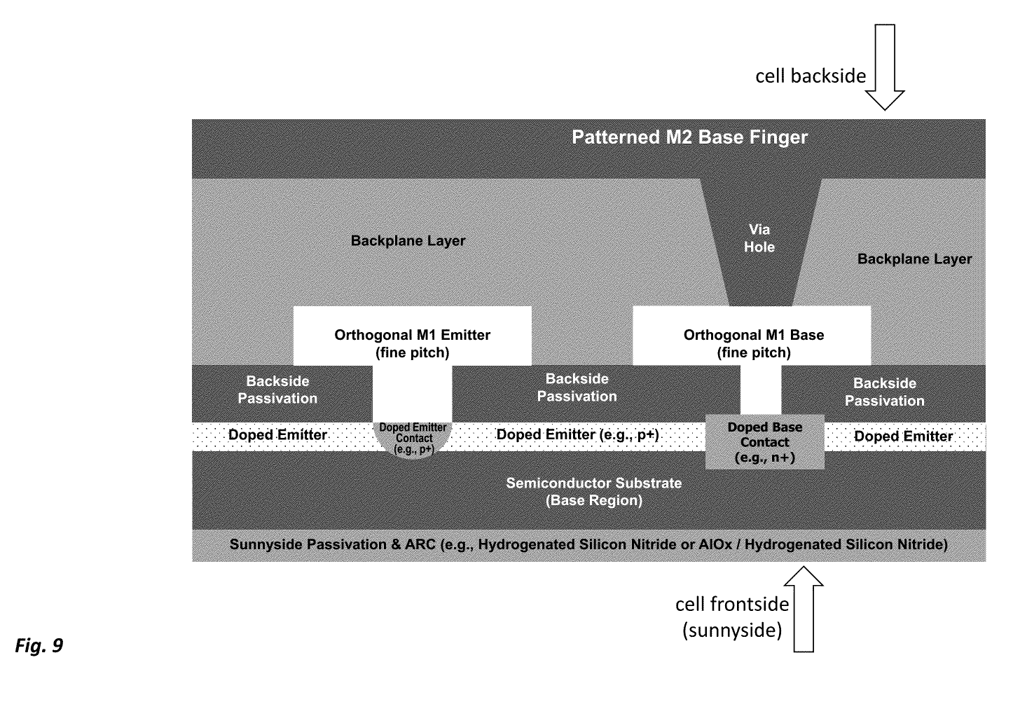

FIGS. 8 and 9 are selected cross-sectional diagrams of portions of a back-contact solar cell along cross-sectional axis showing orthogonal M1/M2 emitter connection and orthogonal M1/M2 base connection, respectively, and are provided as descriptive embodiments to further detail cell architectures which may be used in accordance with the disclosed subject matter. FIG. 8 is a cross-sectional diagram showing a portion of an M1/M2 emitter connection—for example with reference to FIGS. 5 and 6 a cross-sectional along the A axis of FIG. 6 showing the connection between M1 emitter finger 34 and orthogonal M2 emitter finger 44 by via 40. FIG. 9 is a cross-sectional diagram showing a portion of an M1/M2 base connection—for example with reference to FIGS. 5 and 6 a cross-sectional along the B axis of FIG. 6 showing the connection between M1 base finger 32 and orthogonal M2 base finger 42 by via 40.

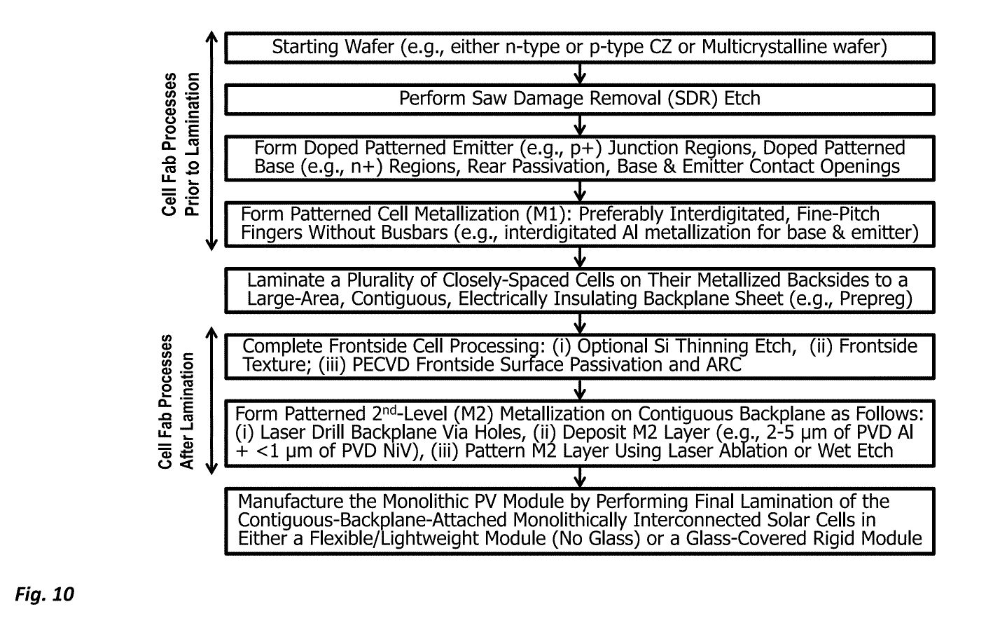

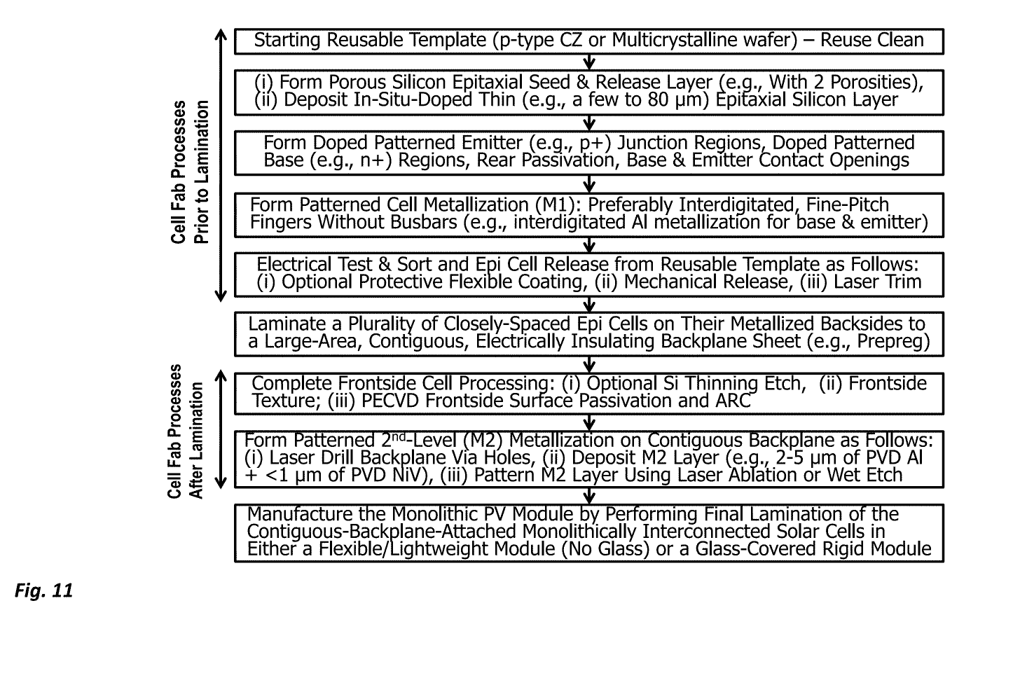

FIGS. 10 and 11 are process flows for forming a monolithic solar cell array/module in accordance with the disclosed subject matter. Portions of exemplary solar cell array/modules resulting from the fabrication according to the process flows of FIGS. 10 and 11 are shown in FIGS. 8 and 9. FIG. 10 is a process flow for fabricating an array/module of back contact back junction solar cells starting with a silicon wafer, for example a CZ or multicrystalline silicon wafer. FIG. 11 is a process flow for fabricating an array/module of back contact back junction solar cells using an epitaxial release (or lift-off) process to form a thin epitaxial silicon solar cell.

Solar cell fabrication methods structures having common inventors may be found in U.S. Pat. Pub. No. 2014-0158193 published Jun. 12, 2014, U.S. Pat. Pub. No. 2013-0288425 published Oct. 31, 2013, U.S. Pat. No. 13/807,631 filed Dec. 28, 2012 (published as PCT Pat. Pub. No. WO2013022479 on Feb. 14, 2013), and U.S. Pat. Pub. No. 2013-0000715 published Jan. 3, 2013, all of which are hereby incorporated by reference in their entirety.

Cell to cell interconnections and module bussing of the solar cell arrays and modules provided herein may be provided by a monolithic patterned M2 metallization without the need for additional tabbing or soldering between the solar cells. In other words, second level metal (M2) may be deposited and patterned across the continuous backplane comprising a plurality of N×M solar cells (and in some instances concurrently forming the conductive via plugs by at least partially covering or filling the vias in the continuous backplane to form electrical connection to on-cell first level metal M1) and subsequently patterned to complete cell level metallization, form cell to cell electrical connections, as well as form desired module bussing pads. Thus M2 structure provides the patterned conductive pathways for voltage and current through the solar cell array using a plurality of solar cells laminated to a continuous backplane. Importantly, if module bussing is desired, for example in the case of a hybrid parallel series connected solar cell array/module, the module bussing may be positioned on the continuous backplane handle (as shown in FIG. 3A) and monolithically formed as M2 metallization—in other words, M2 may be formed outside the active cell area for applications such as module bussing or power electronics placement.

The foregoing description of the exemplary embodiments is provided to enable any person skilled in the art to make or use the claimed subject matter. Various modifications to these embodiments will be readily apparent to those skilled in the art, and the generic principles defined herein may be applied to other embodiments without the use of the innovative faculty. Thus, the claimed subject matter is not intended to be limited to the embodiments shown herein but is to be accorded the widest scope consistent with the principles and novel features disclosed herein.

What is claimed is:

1. A photovoltaic solar cell array, comprising:
a plurality of solar cells, each of said solar cells having at least:
a light receiving frontside and a backside;
a first patterned cell metallization on said backside contacting base regions and emitter regions of said solar cell;
an electrically insulating continuous backplane layer attached to said backsides of said plurality of solar cells and covering said first cell metallization of each of said solar cells;
via holes through said continuous backplane layer to said first cell metallization; and
a second cell metallization connected to said first cell metallization of each of said solar cells and electrically interconnecting said plurality of solar cells in said array.

2. The photovoltaic solar cell of claim 1, wherein said plurality of solar cells is a plurality of back contact solar cells.

3. The photovoltaic solar cell of claim 2, wherein said plurality of back contact solar cells are interdigitated back contact solar cells.

4. The photovoltaic solar cell of claim 1, wherein said first cell metallization further comprises a base busbar and an emitter busbar.

5. The photovoltaic solar cell of claim 1, wherein said second cell metallization further comprises a base busbar and an emitter busbar.

6. The photovoltaic solar cell of claim 1, wherein said continuous backplane layer is a prepreg sheet.

7. The photovoltaic solar cell of claim 6, wherein said continuous prepreg sheet is an aramid fiber resin based prepreg sheet.

8. The photovoltaic solar cell of claim 6, wherein said continuous prepreg sheet has a thickness less than approximately 250 micrometers.

9. The photovoltaic solar cell of claim 1, wherein said solar cells comprise semiconductor absorbers having a thickness less than approximately 100 micrometers.

10. The photovoltaic solar cell of claim 1, wherein second cell metallization electrically connects said plurality of solar cells in an all-series connection.

11. The photovoltaic solar cell of claim 1, wherein second cell metallization electrically connects said plurality of solar cells in a hybrid parallel-series connection.

12. The photovoltaic solar cell of claim 1, wherein said continuous backplane layer forms a handle perimeter around said plurality of solar cells.

13. A method for fabricating a photovoltaic solar cell array, comprising:
laminating a continuous backplane to the backside of a plurality of solar cells;
forming vias through said continuous backplane to base and emitter metallization on the backside of each of said plurality of solar cells;
forming a second level metal M2 on said continuous backplane, said second level metal M2 contacting said base and emitter metallization through said vias in said continuous backplane; and
patterning said second level metal M2 into a base and emitter metallization pattern connecting to said base and emitter metallization on the backside of each of said plurality of solar cells and patterning an interconnection pattern electrically connecting said plurality of solar cells in said array.

14. The method for fabricating a photovoltaic solar cell array of claim 13, wherein said via holes are formed by laser drilling.

15. The method for fabricating a photovoltaic solar cell array of claim 13, wherein said formation of a second level metal M2 on said continuous backplane forms electrically conductive via plugs in said vias.

16. The method for fabricating a photovoltaic solar cell array of claim 13, further comprising the step of at least partially filling said vias with an electrically conductive material prior to or after formation of said second level metal M2.

17. The method for fabricating a photovoltaic solar cell array of claim 13, further comprising solar cell frontside processing after said lamination of a continuous backplane.

18. The method for fabricating a photovoltaic solar cell array of claim 17, wherein said solar cell frontside processing comprises a solar cell thinning etch.

19. The method for fabricating a photovoltaic solar cell array of claim 17, wherein said solar cell frontside processing comprises a solar cell texturization etch.

20. The method for fabricating a photovoltaic solar cell array of claim 17, wherein said solar cell frontside processing comprises frontside passivation by PECVD.

21. A photovoltaic solar cell array, comprising:
a plurality of interdigitated back contact solar cells, each of said solar cells having at least:
a light receiving frontside and a backside;
an interdigitated first cell metallization on said backside contacting base regions and emitter regions of said solar cell;
an electrically insulating continuous backplane layer attached to said backsides of said plurality of solar cells and covering said first cell metallization of each of said solar cells;
via holes through said continuous backplane prepreg sheet to said first cell metallization; and
an interdigitated second cell metallization electrically connected to said first cell metallization of each of said solar cells and electrically connecting said plurality of solar cells in said array, said interdigitated second cell metallization orthogonal to said interdigitated first cell metallization and having at least a base busbar and an emitter busbar corresponding to each of said solar cells.

22. A photovoltaic solar cell array of claim 22, wherein said prepreg sheet is an aramid fiber resin based prepreg sheet.
